(19) United States
(12) Patent Application Publication
(10) Pub. No.: US 2012/0153403 A1
(43) Pub. Date: Jun. 21, 2012

(54) SEMICONDUCTOR DEVICES AND METHODS OF FABRICATING THE SAME

(76) Inventors: Min-chul PARK, Hwaseong-si (KR); Giyoung Yang, Hwaseong-si (KR); Haneul Yoo, Seoul (KR)

(21) Appl. No.: 13/292,508

(22) Filed: Nov. 9, 2011

(30) Foreign Application Priority Data
Dec. 20, 2010 (KR) 10-2010-0130807

(51) Int. Cl. H01L 29/78

(52) U.S. Cl. 257/401; 257/E29.255

(57) ABSTRACT

A semiconductor device includes a substrate, a device isolation layer at the substrate and defining an active region, and a gate electrode on the substrate and extending across the active region. The active region includes a first active region and a second active region, and the first and second active regions are arranged at opposing sides of a centerline of the gate electrode. At least one of the first and second active regions has a width decreasing from a region outside the gate electrode toward the centerline of the gate electrode, and the first and second active regions are asymmetric with respect to the centerline of the gate electrode.

### CROSS-REFERENCE TO RELATED APPLICATIONS

This U.S. patent application claims priority under 35 U.S.C. 119 of Korean Patent Application No. 10-2010-0130807, filed on Dec. 20, 2010, in the Korean Intellectual Property Office, and entitled: “Semiconductor Devices and Methods of Fabricating the Same,” which is incorporated by reference herein in its entirety.

### BACKGROUND

The integration of semiconductor devices is rapidly advancing, e.g., the integration of dynamic random access memories (DRAMs) is rapidly advancing. Accordingly, patterns of semiconductor devices are being more finely formed. While the width of gate lines, e.g., a gate length of transistors, may be decreased, the reliability of transistors should still be maintained and/or improved.

### SUMMARY

Embodiments may be realized by providing a semiconductor device including a substrate, a device isolation layer at the substrate, the device isolation layer defining an active region, and a gate electrode on the substrate, the gate electrode extending across the active region. The active region includes a first active region and a second active region, and the first and second active regions are arranged at opposing sides of a centerline of the gate electrode, at least one of the first and second active regions has a width decreasing from a region outside the gate electrode toward the centerline of the gate electrode, and the first and second active regions are asymmetric with respect to the centerline of the gate electrode.

The first and second active regions may have widths decreasing toward the centerline of the gate electrode. The width of one of the first and second active regions may decrease from the region outside the gate electrode toward the centerline of the gate electrode and the width of another of the first and second active regions may decrease from a region under the gate electrode toward the centerline of the gate electrode.

One of the first and second active regions may have the decreasing width from the region outside the gate electrode toward the centerline of the gate electrode and another of the first and second active regions may have a constant width from another region outside the gate electrode toward the centerline of the gate electrode. The device may include a gate insulation layer between the gate electrode and the active region.

The decreasing width of the at least one of the first and second active regions may have a constant gradient. The decreasing width of the at least one of the first and second active regions may have a concave shape. The decreasing width of the at least one of the first and second active regions may have a convex shape.

Embodiments may also be realized by providing a method that includes forming a device isolation layer on a substrate to define an active region, and forming a gate electrode on the substrate and across the active region. The active region includes a first active region and a second active region, the first and second active regions are arranged at opposing sides of a centerline of the gate electrode, at least one of the first and second active regions has a width decreasing from a region outside the gate electrode toward the centerline of the gate electrode, and the first and second active regions are asymmetric with respect to the centerline of the gate electrode.

The first and second active regions may have widths decreasing toward the centerline of the gate electrode. The width of one of the first and second active regions may decrease from the region outside the gate electrode toward the centerline of the gate electrode and the width of another of the first and second active regions may decrease from a region under the gate electrode toward the centerline of the gate electrode.

One of the first and second active regions may have the decreasing width from the region outside the gate electrode toward the centerline of the gate electrode and another of the first and second active regions may have a constant width from another region outside the gate electrode toward the centerline of the gate electrode.

The decreasing width of the at least one of the first and second active regions may have a constant gradient. The decreasing width of the at least one of the first and second active regions may have a concave shape. The decreasing width of the at least one of the first and second active regions may have a convex shape.

The method may include forming a gate insulation layer between the gate electrode and the active region. The method may include forming impurity regions in the substrate in the first and second active regions, respectively.

Embodiments may also be realized by providing a semiconductor device having a gate electrode, and an active region. The active region includes a first active region abutting a second active region, the first and second active regions having a boundary therebetween, the boundary corresponding to a centerline of the gate electrode, the first and second active regions being asymmetric with respect to the boundary, the first active region having a substantially constant width from or a width decreasing from a region inside the first active region to the boundary, and the second active region having a width decreasing from a region inside the second active region to the boundary.

The first active region may be under the gate electrode and may have the substantially constant width adjacent to the boundary. The second active region may be under the gate electrode and may have a narrowest width adjacent to the boundary.

The first active region may be under the gate electrode and may have the width decreasing from the region inside the first active region to the boundary such that a narrowest width thereof is adjacent to the boundary. The second active region may be under the gate electrode and may have a narrowest width adjacent to the boundary.

The decreasing width of the second active region may have a constant slope. The width of the second active region may exponentially change adjacent to the boundary.

### BRIEF DESCRIPTION OF THE DRAWINGS

Features will become apparent to those of ordinary skill in the art by describing in detail exemplary embodiments with reference to the attached drawings, in which:

FIG. 1A illustrates a plan view for explaining a semiconductor device and a method of fabricating the semiconductor device, according to exemplary embodiments;

FIGS. 1B through 1D illustrate sectional views taken along lines I-I′, II-II′, and III-III′ of FIG. 1A, respectively;

FIGS. 2 through 4 illustrate plan views of semiconductor devices, according to exemplary embodiments;

FIG. 5 illustrates a schematic block diagram of an exemplary memory system including a semiconductor device, according to an exemplary embodiment;

FIG. 6 illustrates a schematic block diagram of an exemplary memory card including a semiconductor device, according to an exemplary embodiment; and

FIG. 7 illustrates a schematic block diagram of a data processing system to which a semiconductor device is included, according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

Like reference numerals refer to like elements throughout. The embodiments are not limited to the specific shape illustrated in the exemplary views. For example, shapes of the exemplary views may be modified according to, e.g., manufacturing techniques and/or allowable errors. The exemplary embodiments may include other shapes that may be created according to, e.g., the manufacturing processes such as an etched region illustrated as a rectangle may have rounded or have curved features. Areas exemplified in the drawings have general properties, and are used to illustrate a specific shape of a semiconductor package region. Thus, this should not be construed as limiting to the scope of the embodiments.

In the following description, the technical terms may be used only for explaining specific exemplary embodiments. The terms of a singular form may include plural forms unless referred to the contrary. The meaning of “include,” “comprise,” “including,” or “comprising,” specifies a property, a region, a fixed number, a stage, a process, an element and/or a component but does not exclude other properties, regions, fixed numbers, stages, processes, elements.

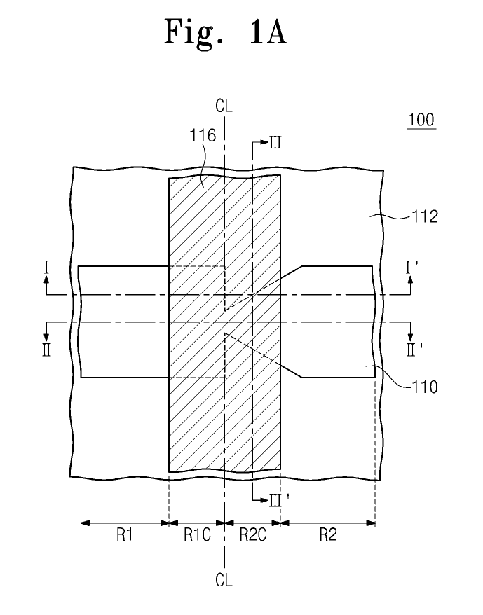

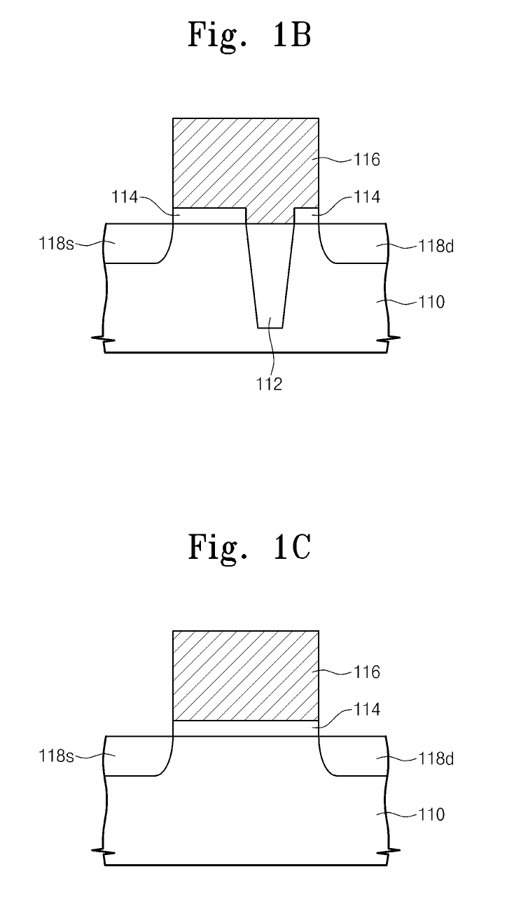

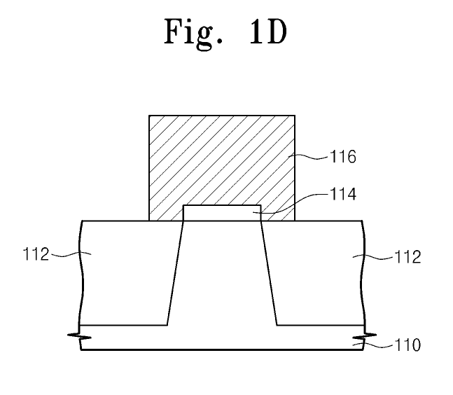

FIG. 1A illustrates a plan view for explaining a semiconductor device and a method of fabricating the semiconductor device according to exemplary embodiments. FIGS. 1B through 1D illustrate sectional views taken along lines I-I′, II-II′, and III-III′ of FIG. 1A, respectively.

Referring to FIGS. 1A through 1D, a semiconductor device 100 may include a transistor. The transistor may include a substrate 110 and a device isolation layer 112 disposed in the substrate 110. The device isolation layer 112 may define an active region on the substrate 110. The transistor may include a gate electrode 116 disposed on the substrate 110 and the gate electrode 116 may extend across the active region, e.g., the gate electrode 116 may be above the active region and cross a width of the active region. The semiconductor substrate 110 may include a plurality of the gate electrodes 116 disposed thereon and a plurality of active regions arranged thereon. Each transistor may include one gate electrode 116 that corresponds to one active region. The transistor may include a gate insulation layer 114 disposed between the gate electrode 116 and the active region.

The substrate 110 may be, e.g., a silicon (Si) substrate. However, embodiments are not limited thereto. The device isolation layer 112 may be formed in the substrate 110 to define the active region such that, e.g., the active region includes a first active region, e.g., regions R1 and R1C, and a second active region, e.g., regions R2 and R2C, at opposing sides of a centerline CL of the gate electrode 116. For example, one active region on the substrate 110 may be divided into a plurality of regions, e.g., the first active region including regions R1 and R1C and the second active region including regions R2 and R2C. According to an exemplary embodiment, the first active region may include a first impurity region R1 and a first channel region R1C. The second active region may include a second impurity region R2 and a second channel region R2C.

The first and second impurity regions R1 and R2 of the substrate 110 may each include one of source and drain regions 118s and 118d of the transistor. For example, as illustrated in FIG. 1B, the first impurity region R1 may include source region 118s and the second impurity region R2 may include the drain region 118d. Accordingly, the source region 118s may be disposed in, e.g., only in, the first impurity region R1, and the drain region 118d may be disposed in, e.g., only in, the second impurity region R2. However, embodiments are not limited thereto. For example, the source region 118s may be disposed in, e.g., only in, the second impurity region R2, and the drain region 118d may be disposed in, e.g., only in, the first impurity region R1.

The first and second channel regions R1C and R2C may be, e.g., may form, a channel region of the transistor. The first and second channel regions R1C and R2C may be adjacent to each other, e.g., may be in an abutting relationship, to form one continuous channel region of the transistor. For example, the first and second channel regions R1C and R2C may be adjacent to opposing sides of the centerline CL. The centerline CL may constitute a boundary between the first and second channel regions R1C and R2C. The first and second channel regions R1C and R2C may be disposed between the first impurity region R1 and the second impurity region R2.

The first active region including regions R1 and R1C may have a substantially constant width in a direction from an outside region to the centerline CL of the gate electrode 116, e.g., as illustrated in FIG. 1A. For example, a width of the first impurity region R1 along a first direction substantially parallel to the centerline CL may be substantially constant from a region adjacent to an outer boundary of the first impurity region R1 to the first channel region R1C. Further, a width of the first channel region R1C along the first direction may be substantially constant from the first impurity region R1 to the centerline CL.

The second active region including regions R2 and R2C may have a decreasing width in a direction from an outside region to the centerline CL of the gate electrode 116, e.g., as illustrated in FIG. 1A. For example, a width of the second channel region R2C along the first direction may increase from the centerline CL to the second impurity region R2 such that the width thereof decreases toward the centerline CL. One portion of the second impurity region R2 may have a width along the first direction that increases from the second channel region R2C to another portion of the second impurity region R2. The other portion of the second impurity region R2 may correspond to an outside region of the gate electrode 116 in the active region. A width of the second impurity region R2 from the one portion of the second impurity region R2 to an outer boundary of the second impurity region R2 may be substantially constant. For example, the substantially constant width of the other portion of the second impurity region R2 may be substantially the same as the width of the first impurity region R1.

The changing width of the second impurity region R2 and the second channel region R2C may have a constant gradient or slope, e.g., may linearly change along a constant gradient. The widths may change within a predetermined range. An upper limit of the predetermined range may correspond to the substantially constant width of the first impurity region R1 and a lower limit of the predetermined range may correspond to a width of the active region on the substrate 110 at the centerline CL of the gate electrode 116. The width of the second channel region R2C and the second impurity region R2 may linearly increase from the centerline CL within the predetermined range.

The first active region including regions R1 and R1C and the second active region including regions R2 and R2C may be asymmetric with respect to the centerline CL of the gate electrode 116.

The gate insulation layer 114 may be disposed between the gate electrode 116 and the active region of the substrate 110. The gate insulation layer 114 may include, e.g., silicon oxide and/or a high dielectric constant material. The silicon oxide may be formed by, e.g., wet thermal oxidation, dry thermal oxidation, and/or chemical vapor deposition (CVD). The high dielectric constant material may have a dielectric constant greater than a dielectric constant of silicon oxide. For example, the high dielectric constant material may have a dielectric constant of about 10 or higher. Examples of the high dielectric constant material include, e.g., silicate, aluminate, or oxide containing at least one metal such as hafnium (Hf), zirconium (Zr), aluminum (Al), titanium (Ti), lanthanum (La), yttrium (Y), gadolinium (Gd), and tantalum (Ta). The gate insulation layer 114 including such a high dielectric constant material may have a single-layer or multilayer structure. The gate insulation layer 114 having the multilayer structure may include a plurality of different layers.

In the case where the gate insulation layer 114 includes the high dielectric constant material, a buffer layer (not shown) may be further disposed between the substrate 110 and the gate insulation layer 114. The buffer layer may include, e.g., a silicon oxide and/or a silicon oxynitride. The buffer layer may, e.g., improve interfacial quality between the substrate 110 and the gate insulation layer 114.

The gate electrode 116 may be disposed on the gate insulation layer 114. The gate electrode 116 may extend in a cross-wise direction across the active region on the substrate 110, e.g., the gate electrode 116 may cross the width of the active region. The gate electrode 116 may be a gate including, e.g., polysilicon and/or metal. The gate electrode 116 may overlap widths of the first and second channel regions R1C and R2C, e.g., the gate electrode 116 may be excluded above the first and second impurity regions R1 and R2.

Without intending to be bound by this theory, the second impurity region R2 and the second channel region R2C may have a decreasing width from the outside region to the centerline CL of the gate electrode 116. Thus, a current and an electric field may be decreased in a border region of the second channel region R2C in the direction of a sidewall oxide layer (not shown) between the substrate 110 and the device isolation layer 112. For example, a generation of hot carriers may be reduced in the border region of the second channel region R2C, and the possibility of hot electron induced punch-through (HEIP) may be reduced and/or prevented.

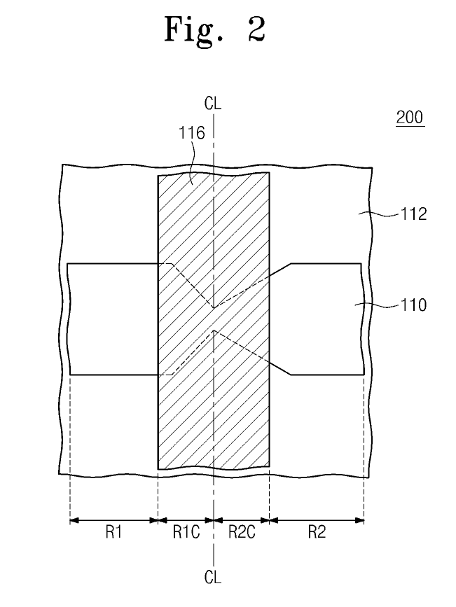

With reference to FIGS. 2 through 4, semiconductor devices will be described according to exemplary embodiments. FIGS. 2 through 4 illustrate plan views of semiconductor devices. In FIGS. 2 through 4, active regions and gate electrodes of the semiconductor devices are mainly illustrated for clarity of description. The same elements as those explained in the previous embodiment are denoted by the same reference numerals, and descriptions thereof will not be repeated.

A semiconductor device 200 shown in FIG. 2, according to an exemplary embodiment, may have a different active region structure in comparison with the semiconductor device 100 illustrated in FIG. 1A.

A first active region including regions R1 and R1C and a second active region including regions R2 and R2C may both have widths decreasing toward a centerline CL of a gate electrode 116. The decreasing widths of the first active region and the second active region may have constant gradients or slopes, e.g., may linearly change along a constant gradient. For example, the first active region may have a decreasing width from an inside region to the centerline CL of the gate electrode 116, and the second active region may have a decreasing width from an outside region to the centerline CL of the gate electrode 116.

According to an exemplary embodiment, a width of a first impurity region R1 along a first direction, which may be substantially parallel to the centerline CL, may be substantially constant from an outside region, e.g., an outer boundary of the first impurity region R1, to a first channel region R1C. One portion of the first channel region R1C may have a width along the first direction that is substantially constant, e.g., that is substantially equal to the width of the first impurity region R1. A width of the first channel region R1C from the one portion of the first channel region R1C having the substantially constant width to the centerline CL may decrease, e.g., by a constant gradient or slope, to the centerline CL. Accordingly, one portion of the first channel region R1C under the gate electrode 116 may have a substantially constant width and another portion of the first channel region R1C under the gate electrode 116 may have a varied width.

A width of a second channel region R2C along the first direction may increase from the centerline CL to a second impurity region R2 such that the width decreases toward the centerline CL by, e.g., a constant gradient. One portion of the second impurity region R2 may have a width along the first direction that increases from the second channel region R2C to another portion of the second impurity region R2. A width of the second impurity region R2 from the one portion of the second impurity region R2 to an outer boundary of the second impurity region R2 may be substantially constant. For example, the substantially constant width of the other portion of the second impurity region R2 may be substantially the same as the width of the first impurity region R1.

According to an exemplary embodiment, since the width of the first active region including regions R1 and R1C may decrease only in a first channel region R1C, the gradient of the decreasing width of the first active region may be greater than the gradient of the decreasing width of the second active region including regions R2 and R2C. The change in width of the first active region may be concentrated only in the first channel region R1C such that the width changes within a predetermined range over a smaller area. In contrast, the change in width of the second active region may be expanded to include the second channel region R2C and the second impurity region R2 such that the width changes over a larger area within the predetermined range. The upper limit of the predetermined range may correspond to the substantially constant width of the first impurity region R1 and the lower limit of the predetermined range may correspond to a width of the active region on the substrate 110 at the centerline CL of the gate electrode 116.

In this way, an active region of the semiconductor device 200 may be constituted by the first active region including the first impurity region R1 and the first channel region R1C and the second active region including the second impurity region R2 and the second channel region R2C, which first and second active regions may be asymmetric with respect to the centerline CL of the gate electrode 116.

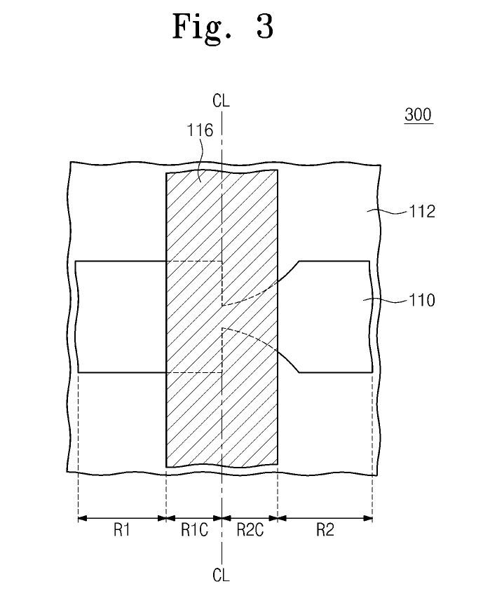

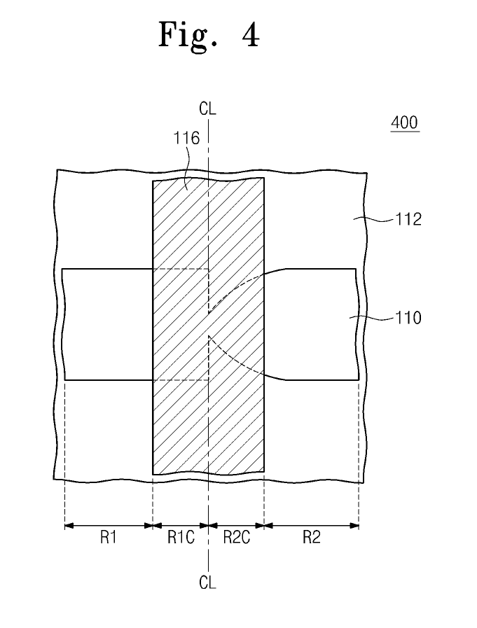

A semiconductor device 300 shown in FIG. 3, according to an exemplary embodiment, may have a different active region structure in comparison with the semiconductor device 100 illustrated in FIG. 1A and the semiconductor device 200 illustrated in FIG. 2.

According to an exemplary embodiment, a first active region may include a first impurity region R1 and a first channel region R1C. The first impurity region R1 and the first channel region R1C may both have a substantially constant width from an outside region, e.g., from an outer boundary of the first impurity region R1, to a centerline CL of a gate electrode 116. A second active region may include a second impurity region R2 and a second channel region R2C. The second channel region R2C and a portion of the second impurity region R2 may have a width decreasing toward the centerline CL of the gate electrode 116. The change in the width may not be constant, e.g., the rate of change or slope may be varied.

The decreasing width of the second active region may have a concave shape, e.g., the width may exponentially change between predetermined upper and lower limits along two opposing lateral sides of the second active region. For example, the two opposing sides of the second active region may have varying slopes, e.g., the slope may increase as a distance from the centerline CL increases. The two opposing lateral sides of the second active region may be symmetrical with respect to each other. The width of the second active region may increase, e.g., exponentially increase, in the second channel region R2C from the centerline CL to a portion of the second impurity region R1 outside the gate electrode 116.

According to an exemplary embodiment, the first impurity region R1 and the first channel region R1C may have a substantially constant width from the outside region to the centerline CL of the gate electrode 116. The second channel region R2C may have a width increasing from the centerline CL to the second impurity region R2. One portion of the second impurity region R2 may have a width increasing from the second channel region R2C to another portion of the second impurity region R2. A width of the second impurity region R2 from the one portion of the second impurity region R2 to an outer boundary of the second impurity region R2 may be substantially constant, e.g., may be equal to the substantially constant width of the first impurity region R1 and the first channel region R1CC. The change in width of the second impurity region R2 and the second channel region R2C may be within a predetermined range. The upper limit of the predetermined range may correspond to the substantially constant width of the first impurity region R1 and the first channel region R1C. The lower limit of the predetermined range may correspond to a width of the active region on the substrate 110 at the centerline CL of the gate electrode 116.

In this way, an active region of the semiconductor device 300 may be constituted by the first active region including the first impurity region R1 and the first channel region R1C and the second active region including the second impurity region R2 and the second channel region R2C, which first and second active regions may be asymmetric with respect to the centerline CL of the gate electrode 116.

A semiconductor device 400 shown in FIG. 4, according to an exemplary embodiment, may have a different active region structure in comparison with the semiconductor device 100 illustrated in FIG. 1A, the semiconductor device 200 illustrated in FIG. 2, and the semiconductor device 300 illustrated in FIG. 3.

A first active region may include a first impurity region R1 and a first channel region R1C. The first impurity region R1 and the first channel region R1C may have a constant width from an outside region, e.g., an outer boundary of the first impurity region R1, to a centerline CL of a gate electrode 116. A second active region may include a second impurity region R2 and a second channel region R2C. The second active region may have a width decreasing toward the centerline CL of the gate electrode 116.

The decreasing width of the second active region may have a convex shape, e.g., the width may exponentially decrease to the centerline CL of the gate electrode 116 along two opposing lateral sides of the second active region. For example, the two opposing sides of the second active region may have varying slopes, e.g., the slope may increase as a distance from the centerline CL decreases. The two opposing lateral sides of the second active region may be symmetrical with respect to each other. The width of the second active region may exponentially decrease in a portion of the second impurity region R1 and through the second channel region R2C to the centerline CL.

According to an exemplary embodiment, the first impurity region R1 and the first channel region R1C may have a substantially constant width from the outside region to the centerline CL of the gate electrode 116. The second channel region R2C may have a width increasing from the centerline CL to the second impurity region R2. One portion of the second impurity region R2 may have a width increasing from the second channel region R2C to another portion of the second impurity region R2. A width of the second impurity region R2 from the one portion of the second impurity region R2 to a region outside the second impurity region R2 may be substantially constant, e.g., may be equal to the substantially constant width of the first impurity region R1 and the first channel region R1C. The change in width of the second impurity region R2 and the second channel region R2C may be within a predetermined range. The upper limit of the predetermined range may correspond to the substantially constant width of the first impurity region R1 and the first channel region R1C. The lower limit of the predetermined range may correspond to a width of the active region on the substrate 110 at the centerline CL of the gate electrode 116.

In this way, an active region of the semiconductor device 400 may be constituted by the first active region including the first impurity region R1 and the first channel region R1C and the second active region including the second impurity region R2 and the second channel region R2C, which first and second active regions may be asymmetric with respect to the centerline CL of the gate electrode 116.

Embodiments are not limited to the exemplary embodiments discussed above. For example, the second active region may include a second impurity region R2 and a second channel region R2C having a substantially constant width. Further, a width of the first active region, e.g., a width in at least one of a first impurity region R1 and a first channel region R1C, may be varied.

In the semiconductor devices of the exemplary embodiments, the width the active region may be reduced from outside regions to the centerline CL of the gate electrode 116, and the active region may be asymmetric with respect to the centerline CL of the gate electrode 116. For example, a narrowest width of the active region may be at the centerline CL of the gate electrode 116 such that the width of at least one of the first and second active regions may increase away from the centerline CL. The widths of the first and second active regions may be substantially constant, may abruptly change, may gradually change, and/or may exponentially change in a direction away from the centerline CL. The widths of the active region may be substantially constant in an area surrounding the gate electrode 116 such that the width of the active region may be varied in an area under the gate electrode 116. Accordingly, the width of at least one of the first and second active regions may decrease from an area outside the gate electrode 116, e.g., an area having a non-overlapping relationship with the gate electrode 116, to the centerline CL.

The active region, according to an exemplary embodiment, may reduce the possibility of and/or prevent deterioration of transistors of the semiconductor devices caused by, e.g., hot electron induced punch-through (HEIP). Accordingly, reliable of the semiconductor devices including transistors may be improved. For example, in the case of transistors having gate electrodes with gate tab and ring type gate electrodes, the possibility of deterioration of the transistors caused by HEIP may be reduced and/or more surely prevented. Therefore, the reliability of the semiconductor devices including these types of transistors may be improved.

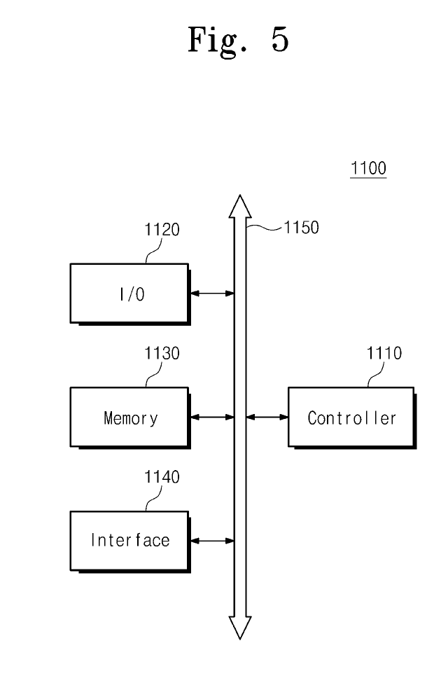

FIG. 5 illustrates a schematic block diagram of an exemplary memory system including a semiconductor device, according to an exemplary embodiment.

Referring to FIG. 5, a memory system 1100 may be applied to, e.g., a personal digital assistant (PDA), a portable computer, a web tablet, a wireless phone, a mobile phone, a digital music player, a memory card, and/or any other devices capable of wirelessly receiving and transmitting data.

The memory system 1100 may include a controller 1110 and an input/output (I/O) unit 1120 such as a key pad, a key board, and/or a display device. The memory system 1100 may include a memory 1130, an interface 1140, and a bus 1150. At least the memory 1130 and the interface 1140 may communicate with each other through the bus 1150.

The controller 1110 may include, e.g., at least one microprocessor, a digital signal processor, a microcontroller, and/or other similar processors. The memory 1130 may store commands of the controller 1110. The I/O unit 1120 may receive and/or transmit data or signals between the memory system 1100 and external devices. For example, the I/O unit 1120 may include a key board, a key pad, and/or a display device.

The memory 1130 may include a semiconductor device, according to exemplary embodiments. The memory 1130 may further include another memory such as a different kind of memory, a volatile memory which is accessible at any time, and various other types of memories. The interface 1140 may transmit and receive data to and from a communication network.

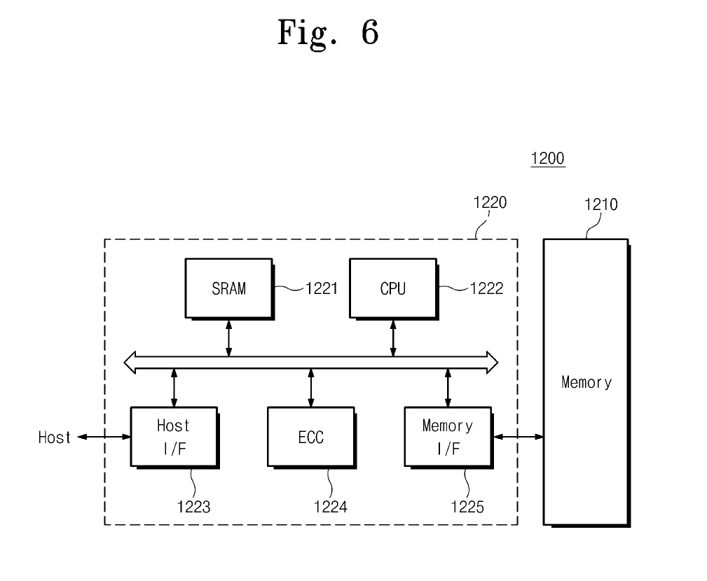

FIG. 6 illustrates a schematic block diagram of an exemplary memory card including a semiconductor device, according to an exemplary embodiment.

Referring to FIG. 6, a memory card 1200 may support a large-capacity data storage and may include a memory 1210 having a semiconductor device, according to an exemplary embodiment. The memory card 1200 may include a memory controller 1220 adapted to control overall data exchange between a host and the memory 1210.

The memory controller 1220 may include a static random access memory (SRAM) 1221 that may be used as an operation memory of a central processing unit (CPU) 1222. The CPU 1222 may control overall data exchange operations of the memory controller 1220. A host interface 1223 may include a data exchange protocol of the host connected with the memory card 1200. An error correction coding (ECC) block 1224 may detect and correct errors included in data read out from the memory 1210 having, e.g., multi-bit characteristics. A memory interface 1225 may interface with the memory 1210 including a semiconductor device, according to an exemplary embodiment. It may be apparent to those of ordinary skill in the art that the memory card 1200 may further include, e.g., a read only memory (ROM) (not shown) storing code data for interface with the host.

As described above, according to exemplary embodiments, highly integrated semiconductor devices, memory cards, and memory systems may be provided. In addition, the semiconductor devices may be applied to recent memory systems such as solid sate drive (SSD). Therefore, highly integrated memory systems may be realized.

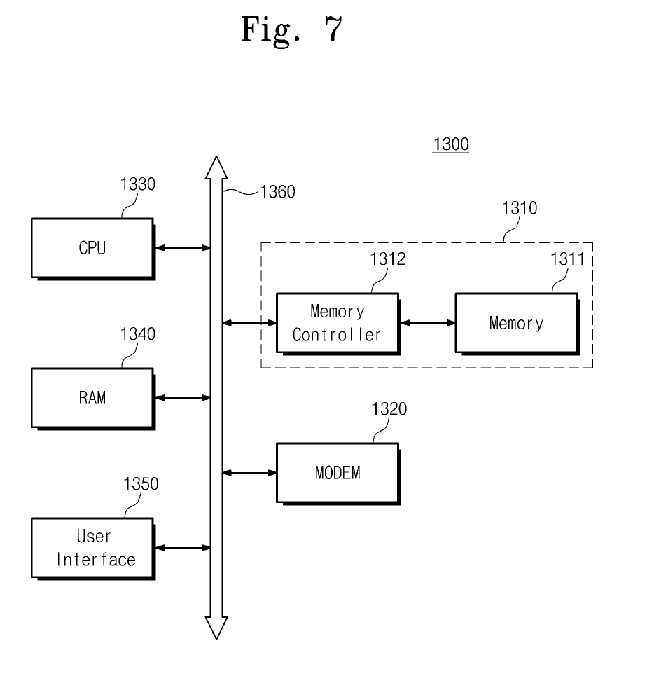

FIG. 7 illustrates a schematic block diagram of a data processing system to which a semiconductor device may be included, according to an exemplary embodiment.

Referring to FIG. 7, a data processing system 1300 may be a mobile device or a desktop computer. The data processing system 1300 may include a memory system 1310. The memory system 1310 may include a memory 1311 having a semiconductor device, according to an exemplary embodiment, and a memory controller 1312 configured to control data exchange between the memory 1311 and a system bus 1360. The data processing system 1300 may include the memory system 1310, a MOdulator and DEModulator (MODEM) 1320, a CPU 1330, a RAM 1340, and a user interface 1350, which may be connected to each other through the system bus 1360.

The memory system 1310 may be similar to and/or substantially the same as the memory system 1100 explained with reference to FIG. 5. The memory system 1310 may store data processed by the CPU 1330 or input from an external device. The memory system 1310 may be a SSD. The data processing system 1300 may store a large amount of data, e.g., stably, in the memory system 1310. Since the memory system 1310 may be highly reliable, resources required for error correction may be reduced. Accordingly, the memory system 1310 may provide a high-speed data exchange function to the data processing system 1300. It may be apparent to those of ordinary skill in that art that the data processing system 1300 may further include another device (not shown) such as an application chipset, a camera image signal processor (ISP), and/or an I/O device.

Memories or memory systems including semiconductor devices, according to exemplary embodiments, may be mounted in various kinds of packages. The various kinds of packages in which memories or memory systems may be mounted include, e.g., Package on Package (PoP), Ball Grid Arrays (BGAs), Chip Scale Packages (CSPs), Plastic Leaded Chip Carrier (PLCC), Plastic Dual In-line Package (PDIP), die in waffle pack, die in wafer form, Chip On Board (COB), CERamic Dual In-line Package (CERDIP), plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level processed Stack Package (WSP).

As described above, in the semiconductor devices of the exemplary embodiments, the active region may have decreasing widths from outside regions to the centerline CL of the gate electrode 116. Further, first and second active regions may be asymmetric with respect to the centerline CL of the gate electrode 116. Accordingly, the transistors of the semiconductor devices may not be deteriorated by HEIP. For example, reliable semiconductor devices and methods of fabricating the semiconductor device may be provided.

In the case of transistors having gate electrodes with, e.g., a gate tab and ring type gate electrodes, the possibility of deterioration of the transistors caused by HEIP can be reduced and/or more surely prevented. Therefore, more reliable semiconductor devices including transistors may be provided.

By way of summation and review, if the gate length of a p-type metal-oxide-semiconductor (PMOS) transistor is reduced, the electrical characteristics of the PMOS transistor may be deteriorated. For example the electrical characteristics may be deteriorated due to hot electron induced punch-through (HEIP), which may be a punch-through induced by hot electrons generated at an edge region of an active region adjoining a device isolation layer.

During operation of a semiconductor device, e.g., having a PMOS transistor, hot electrons having abnormally high energy may be generated because of, e.g., a high potential applied to a channel region therein. Then, atoms of a semiconductor substrate may be ionized by collision with the hot electrons. Accordingly, electron-hole pairs (EHPs) may be generated. At this time, the hot electrons having abnormally high energy may penetrate a gate insulation layer and may become trapped in the gate insulation layer, or may penetrate a device isolation layer and may become trapped in a sidewall oxide layer and/or a liner nitride layer. This phenomenon may be referred to as hot electron induced punch-through (HEIP).

Current leakage in the semiconductor device may occur due to the HEIP. For example, a leakage current may flow along an interface between a gate electrode and a lower active region. This may substantially reduce the length of a channel region. For example, although the physical length of the channel region formed at the interface between the gate electrode and the lower active region is not changed, the electrical length of the channel region may be reduced.

In contrast, embodiments relate to a semiconductor device including a more reliable transistor and a method of fabricating the semiconductor device. Embodiments relate to a semiconductor device and a method of manufacturing that include a reliable transistor configured to reduce the possibility of and/or prevent deterioration caused by hot electron induced punch-through (HEIP).

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. To the maximum extent allowed by law, the scope of the inventive concept is to be determined by the broadest permissible interpretation of the following claims and their equivalents. Accordingly, it will be understood by those of skill in the art that various changes in form and details may be made without departing from the spirit and scope of the present invention as set forth in the following claims.

1. A semiconductor device, comprising:
a substrate;
a device isolation layer at the substrate, the device isolation layer defining an active region; and
a gate electrode on the substrate, the gate electrode extending across the active region, wherein:
the active region includes a first active region and a second active region, the first and second active regions being arranged at opposing sides of a centerline of the gate electrode,
at least one of the first and second active regions has a width decreasing from a region outside the gate electrode toward the centerline of the gate electrode, and
the first and second active regions are asymmetric with respect to the centerline of the gate electrode.

2. The semiconductor device as claimed in claim 1, wherein:
the first and second active regions have widths decreasing toward the centerline of the gate electrode, and
the width of one of the first and second active regions decreases from the region outside the gate electrode toward the centerline of the gate electrode, and the width of another of the first and second active regions decreases from a region under the gate electrode toward the centerline of the gate electrode.

3. The semiconductor device as claimed in claim 1, wherein one of the first and second active regions has the decreasing width from the region outside the gate electrode toward the centerline of the gate electrode and another of the first and second active regions has a constant width from another region outside the gate electrode toward the centerline of the gate electrode.

4. The semiconductor device as claimed in claim 1, wherein the decreasing width of the at least one of the first and second active regions has a constant gradient.

5. The semiconductor device as claimed in claim 1, wherein the decreasing width of the at least one of the first and second active regions has a concave shape.

6. The semiconductor device as claimed in claim 1, wherein the decreasing width of the at least one of the first and second active regions has a convex shape.

7. The semiconductor device as claimed in claim 1, further comprising a gate insulation layer between the gate electrode and the active region.

8-15. (canceled)

16. A semiconductor device, comprising:
a gate electrode; and
an active region including:
a first active region abutting a second active region, the first and second active regions having a boundary therebetween, and the boundary corresponding to a centerline of the gate electrode,
the first and second active regions being asymmetric with respect to the boundary,
the first active region having a substantially constant width from or a width decreasing from a region inside the first active region to the boundary, and
the second active region having a width decreasing from a region inside the second active region to the boundary.

17. The semiconductor device as claimed in claim 16, wherein:
the first active region is under the gate electrode and has the substantially constant width adjacent to the boundary, and
the second active region is under the gate electrode and has a narrowest width adjacent to the boundary.

18. The semiconductor device as claimed in claim 16, wherein:
the first active region is under the gate electrode and has the width decreasing from the region inside the first active region to the boundary such that a narrowest width thereof is adjacent to the boundary, and
the second active region is under the gate electrode and has a narrowest width adjacent to the boundary.

19. The semiconductor device as claimed in claim 16, wherein the decreasing width of the second active region has a constant slope.

20. The semiconductor device as claimed in claim 16, wherein the width of the second active region exponentially changes adjacent to the boundary.
